(19) United States
(12) Patent Application Publication
(10) Pub. No.: US 2017/0103978 A1
(43) Pub. Date: Apr. 13, 2017

(54) Switch Circuit, Semiconductor Device and Method

(71) Applicant: Infineon Technologies Austria AG, Villach (AT)

(72) Inventors: Gerhard Prechtl, Rosegg (AT); Oliver Haeberlen, St. Magdalen (AT); Clemens Ostermaier, Villach (AT)

(21) Appl. No.: 15/291,940

(22) Filed: Oct. 12, 2016

(30) Foreign Application Priority Data
Oct. 13, 2015 (DE) 102015117395.6

(51) Int. Cl. H01L 27/06; H01L 29/778; H01L 29/20; H02M 1/42; H01L 29/423; H01L 23/495; H01L 21/48; H01L 29/747; H01L 29/205

(52) U.S. Cl. CPC H01L 27/0623; H01L 29/747; H01L 29/7787; H01L 29/2003; H01L 29/205; H01L 29/42316; H01L 23/49503; H01L 23/4952; H01L 23/49562; H01L 23/49575; H01L 21/4825; H02M 1/42

(57) ABSTRACT

In an embodiment, a switch circuit includes a bidirectional switch including a first input/output node, a second input/output node, a first diode and a second diode. The first diode and the second diode are coupled anti-serially between the first input/output node and the second input/output node.

### BACKGROUND

To date, transistors used in power electronic applications have typically been fabricated with silicon (Si) semiconductor materials. Common transistor devices for power applications include Si CoolMOS®, Si Power MOSFETs, and Si Insulated Gate Bipolar Transistors (IGBTs). More recently, silicon carbide (SiC) power devices have been considered. Group III-N semiconductor devices, such as gallium nitride (GaN) devices, are now emerging as attractive candidates to carry large currents, support high voltages and to provide very low on-resistance and fast switching times.

For some applications, such as power factor correction (PFC), a bidirectional switch device which can block voltage in two directions may be useful.

### SUMMARY

In an embodiment, a switch circuit includes a bidirectional switch comprising a first input/output node, a second input/output node, a first diode and a second diode. The first diode and the second diode are coupled anti-serially between the first input/output node and the second input/output node.

In an embodiment, a semiconductor device includes a Group III-nitride-based High Electron Mobility Transistor configured as a bidirectional switch. The High Electron Mobility Transistor includes a first input/output contact pad and a second input/output contact pad, one or more gates arranged between the first input/output contact pad and the second input/output contact pad, a first diode and a second diode. The first diode and the second diode are coupled anti-serially between the first input/output contact pad and the second input/output contact pad.

In an embodiment, a method includes coupling a back side of a High Electron Mobility Transistor configured as a bidirectional switch to near source potential by coupling a first diode and a second diode anti-serially between a first input/output contact pad and a second input/output contact pad of the bidirectional switch.

In an embodiment, a method includes coupling a back side of a High Electron Mobility Transistor configured as a bidirectional switch to near drain potential by coupling a first diode and a second diode anti-serially between a first input/output contact pad and a second input/output contact pad of the High Electron Mobility Transistor.

In an embodiment, a semiconductor device is provided which includes a Group III-nitride-based High Electron Mobility Transistor configured as a bidirectional switch. The Group III-nitride-based. High Electron Mobility Transistor includes a first input/output contact pad, a second input/output contact pad, two independently operable gates arranged between the first input/output contact pad and the second. input/output contact pad and a further pad. The further pad is coupled to a rear side of the Group III-nitride-based High Electron Mobility Transistor.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic diagram of a switch circuit.

FIG. 2 illustrates a schematic cross-sectional view of a semiconductor device with a single gate.

FIG. 3 illustrates a schematic cross-sectional view of a dual gated semiconductor device.

FIG. 4 illustrates a schematic view of a semiconductor device.

FIG. 5 illustrates a schematic view of a semiconductor device.

FIG. 6 illustrates a schematic view of a semiconductor device including a conductive via.

FIG. 7 illustrates a schematic view of a semiconductor device including a bond wire connection.

FIG. 8 illustrates a schematic view of a semiconductor device including a substrate coupled to source potential.

FIG. 9 illustrates a schematic cross-sectional view of a semiconductor device including a substrate coupled to source potential.

FIG. 10 illustrates a schematic view of an enhancement mode semiconductor device including a bidirectional switch.

FIG. 11 illustrates a schematic view of a Group III nitride-based device including a bidirectional switch.

FIG. 12 illustrates a schematic view of a semiconductor device including a substrate coupled to drain potential.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure (s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, the terms “coupled” and/or “electrically coupled” are not meant to mean that the elements must be directly coupled together-intervening elements may be provided between the “coupled” or “electrically coupled” elements.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A depletion-mode device, such as a depletion-mode transistor, has a negative threshold voltage which means that it can conduct current at zero gate voltage. These devices are normally on. An enhancement-mode device, such as an enhancement-mode transistor, has a positive threshold voltage which means that it cannot conduct current at zero gate voltage and is normally off.

As used herein, a “high-voltage device”, such as a high--voltage depletion-mode transistor, is an electronic device which is optimized for high-voltage switching applications. That is, when the transistor is off, it is capable of blocking high voltages, such as about 300 V or higher, about 600 V or higher, or about 1200 V or higher, and when the transistor is on, it has a sufficiently low on-resistance (RON) for the application in which it is used, i.e., it experiences sufficiently low conduction loss when a substantial current passes through the device. A high-voltage device can at least be capable of blocking a voltage equal to the high-voltage supply or the maximum voltage in the circuit for which it is used. A high-voltage device may be capable of blocking 300 V, 600 V, 1200 V, or other suitable blocking voltage required by the application.

As used herein, a “low-voltage device”, such as a low-voltage enhancement-mode transistor, is an electronic device which is capable of blocking low voltages, such as between 0 V and V_{low}, but is not capable of blocking voltages higher than V_{low}. V_{low} may be about 10 V, about 20 V, about 30 V, about 40 V, or between about 5 V and 50 V, such as between about 10 V and 30 V.

As used herein, the phrase “Group III-Nitride” refers to a compound semiconductor that includes nitrogen (N) and at least one Group III element, including aluminum (Al) , gallium (Ga), indium (In), and boron (B), and including but riot limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}, and aluminum indium gallium arsenide phosphide nitride (AlₓIn_{y}Ga_{(1-x-y)}ASₐPbN_{1-a-b)}), for example. Aluminum gallium nitride and AlGaN refers to an alloy described by the formula AlₓGa₍₁₋ₓ₎N, where 0<x<1.

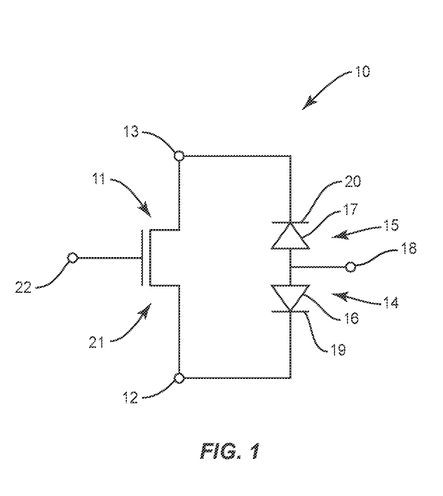

FIG. 1 illustrates a schematic circuit diagram of a switch circuit 10 which includes a bidirectional switch 11 including a first input/output node 12, a second input/output node 13, a first diode 14 and a second diode 15. The first diode 14 and the second diode 15 are coupled anti-serially between the first input/output node 12 and the second input/output node 13.

When the first input/output node 12 acts as an input, the second input/output node 13 acts as the output of the bidirectional switch 11. When the second input/output node 13 acts as the input to the bidirectional switch 11, the first input/output node 12 acts as the output of the bidirectional switch 11. The switch circuit 10 is bidirectional and can be used to block voltage in opposing directions.

Each of the diodes 14, 15 includes a cathode and an anode. The anode 16 of the first diode 14 and the anode 17 of the second diode 15 are coupled to a node 18. The node 18 may be coupled to near source potential.

The cathode 19 of the first diode 14 is electrically coupled to the first input/output node 12. The cathode 20 of the second diode 15 is electrically coupled to the second input/output node 13.

The bidirectional switch 11 may be provided by a single transistor device 21. The single transistor device 21 may be a high-voltage device or a low voltage device and, in one embodiment, includes a Group III nitride-based high Electron Mobility Transistor (HEMT).

In a bidirectional switch, the source potential is not fixed to a dedicated terminal as the source and the drain are interchangeable. The diodes 14, 15 are configured to withstand the maximum blocking voltage rating of the device forming the bidirectional switch 10. Due to the provision of the two anti-serially coupled diodes 14, 15, a single HEMT device 21 may provide a bidirectional switch 10 in which the input is coupled to near source potential in both switching directions. An additional voltage corresponding to the forward voltage drop of the diode is included in the source potential. Consequently, the potential is slightly different from the pure source potential and is termed herein “near source” potential. In embodiments in which the source is coupled to ground potential, for example a low side switch, the potential may be termed “near ground” potential due to the forward voltage drop of the diode.

The diodes may be coupled in an antiserial arrangement between the first input/output contact pad and the second input/output pad such that the cathode of the first diode and the cathode of the second diode are coupled to the backside of the HEMT 211 and the anode of the first diode is coupled to the first input/output contact pad and the anode of the second diode is coupled to the second input/output pad in order to couple the back side of the HEMT to drain potential. In embodiments in which the back side is coupled to drain potential, the potential may be termed “near drain” potential due to the forward voltage drop of the diode.

In some embodiments, in which the bidirectional switch is provided by a HEMT 21, the node 18 and, therefore, the anode 16 of the first diode 14 and the anode 17 of the second diode 15 are electrically coupled to the backside of the HEMT 21. The node 18 may be electrically coupled to the backside of the HEMT 21 by an electrically conductive bond wire or an electrically conductive via which extends through the body of the HEMT 21.

It is useful that the backside of the transistor device is coupled to source potential in order to minimise dynamic effects such as gate lag and drain lag phenomena. In a bidirectional switch, the source potential is not fixed to a dedicated terminal as the source and the drain are interchangeable.

The diodes 14, 15 are configured to withstand the maximum blocking voltage rating of the HEMT 21. Due to the provision of the two anti-serially coupled diodes 14, 15, a single transistor device 21 may provide a bidirectional switch 11 in which the backside of the transistor device 21 is coupled to near source potential or near ground potential in both directions.

The Group III nitride-based HEMT may include a single gate 22 or two independently operable gates. In embodiments in which the Group III nitride-based HEMT 21 includes a single gate, the single gate may be arranged symmetrically, i.e. equidistant, between a first input/output contact pad and a second input/output contact pad of the HEMT. This arrangement may be used to achieve a substantially symmetrical voltage blocking capability in both directions. The first input/output contact pad may provide the first input/output node and the second input/output contact pad may provide the second input/output node. The input/output contact pads may also be denoted as a source/drain contact pad.

In embodiments in which the Group III nitride-based HEMT includes two independently operable gates, each of the gates may be arranged at substantially the same distance from one of the input/output contact pads. This arrangement may be used to achieve a substantially symmetrical voltage blocking capability between the two gates.

In some embodiments, a bidirectional switch is provided which has a different voltage blocking capability in the two opposing directions, for example 600V in a first direction and 100V in the opposing direction, or 66V in a first direction and 12V in the opposing direction.

In embodiments, in which the Group III nitride-based HEMT 21 includes a single gate, the single gate may be arranged asymmetrically, i.e. at different distances, from a first input/output contact pad and a second input/output contact pad of the HEMT.

The HEMT may be a lateral device in that the first input/output node, second input/output node and gate or gates are arranged on a common side of the semiconductor body of the device.

The first diode 14 and the second diode 15 may be provided by discrete components. In other embodiments, the first diode 14 and the second diode 15 are integrated into the transistor device, for example the Group III nitride-based HEMT.

In an embodiment, a semiconductor device is provided which includes a Group III nitride-based High Electron Mobility Transistor (HEMT) configured as a bidirectional switch. The Group III nitride-based HEMT includes a first input/output contact pad and the second input/output contact pad, one or more gates arranged between the first input/output contact pad and the second input/output output contact pad, a first diode and a second diode. The first diode and second diode are coupled anti-serially between the first input output contact pad and the second input output contact pad.

The HEMT may have a voltage blocking rating and the diodes may be configured to withstand this blocking voltage rating.

A cathode of the first diode may be coupled to the first input/output contact pad and a cathode of the second diode may be coupled to the second input/output contact pad of the Group III nitride-based HEMT. An anode of the first diode and an anode of the second diode may be coupled to the backside of the HEMT.

This arrangement enables the back side of the HEMT to be coupled to near source potential or near ground potential when the current flows through the semiconductor device from the first input/output contact pad to the second input/output contact pad and when the current flows in the opposing direction from the second input/output contact pad to the first input/output contact pad.

In some embodiments, a cathode of the first diode and a cathode of the second diode are coupled to a back side of the High Electron Mobility Transistor. This enables the back side of the HEMT to be coupled to near drain potential when the current flows through the semiconductor device from the first input/output contact pad to the second input/output contact pad and when the current flows in the opposing direction from the second input/output contact pad to the first input/output contact pad.

The first diode and the second diode may be provided in the form of discrete components. However, in some embodiments, first diode and the second diode may be integrated into the transistor structure of the bidirectional switch. For example, one or more transistor cells of the transistor device, such as the Group III nitride-based HEMT, may be configured as a first diode which is coupled such that its cathode is coupled to the first or second input/output contact pad and its anode is coupled to the node common with the anode of a second diode.

The first diode and the second diode may each include a transistor structure comprising a first current electrode, a gate and a second current electrode. The gate may be electrically coupled to the first current electrode to form the anode which is coupled to the backside of the HEMT. The second current electrode forms the cathode of the diode and is electrically coupled to the input/output contact pad.

The transistor structure of the transistor device may include an enhancement mode transistor structure or a depletion mode transistor structure. However, in both cases, the transistor structure of the cell or cells providing the diodes has an enhancement mode transistor structure. An enhancement mode transistor structure may include a recessed gate and/or a p-doped Group III nitride layer arranged between the gate metal and semiconductor material of the Group III nitride-based HEMT. The p-doped Group III nitride layer may include a single layer of p-doped GaN or p-doped aluminium gallium nitride AlₓGa₍₁₋ₓ₎N, where 0<x<1. The p-doped Group III-nitride may also include two or more sublayers. In some embodiments, the Group III-nitride-based High Electron Mobility Transistor includes a stack including a p-doped aluminium gallium nitride layer, a p-doped gallium nitride layer arranged on the p-doped aluminium gallium nitride layer and a gate arranged on the p-doped gallium nitride layer to form an enhancement mode device.

The Group III nitride-based HEMT may include a channel layer and a barrier layer arranged on the channel layer. The input/output contact pads and the one or more gate contact pads may be arranged on the barrier layer. The channel layer may include gallium nitride GaN and barrier layer may include aluminium gallium nitride AlₓGa₍₁₋ₓ₎N, where 0<x<1.

The barrier layer may include a spatially varying aluminium content. For example, the aluminium content may vary over the thickness of the barrier layer. In some embodiments, the barrier layer has a graded composition such that the aluminium content gradually increases and the gallium content gradually decreases an a direction from the channel layer to the gate. In some embodiments, the barrier layer includes two or more sublayers, each including aluminium gallium nitride having different aluminium content and, consequently, a different gallium content.

The channel layer may be arranged on a substrate. The substrate may include silicon, silicon carbide or sapphire. One or more buffer layers or transition layers may be arranged between the substrate and the channel layer.

A method is also provided which includes coupling a backside of a High Electron Mobility Transistor (HEMT) configured as a bidirectional switch to near source potential by coupling a first diode and a second diode anti-serially between a first input/output contact pad and a second input/output contact pad of the HEMT.

The HEMT has a blocking voltage rating and the diodes are configured to withstand the blocking voltage rating of the HEMT.

The anode of the first diode and an anode of the second diode may be coupled to the backside of the HEMT. A cathode of the first diode may be coupled to the first input/output contact pad and a cathode of the second diode coupled to the second input/output contact pad to couple the back side of the HEMT to near source potential.

A method is also provided which includes coupling a back side of a High Electron Mobility Transistor configured as a bidirectional switch to near drain potential by coupling a first diode and a second diode anti-serially between a first input/output contact pad and a second input/output contact pad of the High Electron Mobility Transistor.

A cathode of the first diode and a cathode of the second diode are coupled to the back side of the High Electron Mobility Transistor and an anode of the first diode is coupled to the first input/output contact pad and an anode of the second diode is coupled to the second input/output contact pad to couple the back side of the HEMT to near drain potential.

A semiconductor device is provided which includes a Group III-nitride-based High Electron Mobility Transistor configured as a bidirectional switch. The Group III-nitride-based High Electron Mobility Transistor includes a first input/output contact pad, a second input/output contact pad, two independently operable gates arranged between the first input/output contact pad and the second input/output contact pad and a further pad. The further pad is coupled to a rear side of the Group III-nitride-based High Electron Mobility Transistor.

The further pad may be arranged between the two independently operable gates. The further pad may be functionally symmetrically positioned between the two gate pads such that the blocking voltage of the bidirectional switch is the same in the two opposing directions.

The further pad may be arranged on a barrier layer of the Group III-nitride-based High Electron Mobility Transistor and may be electrically coupled to the rear side of the Group III-nitride-based High Electron Mobility Transistor by a conductive via which extends through the semiconductor body of the Group III-nitride-based High Electron Mobility Transistor, or an electrical connection external to the Group III-nitride-based High Electron Mobility Transistor.

The further pad may be coupled to source potential or near source potential in embodiments in which the rear side of the Group III nitride-based High Electron Mobility Transistor is coupled to source potential or near source potential or be coupled to drain potential or near drain potential in embodiments in which the rear side of the Group III nitride-based High Electron Mobility Transistor is coupled to drain potential or near drain potential.

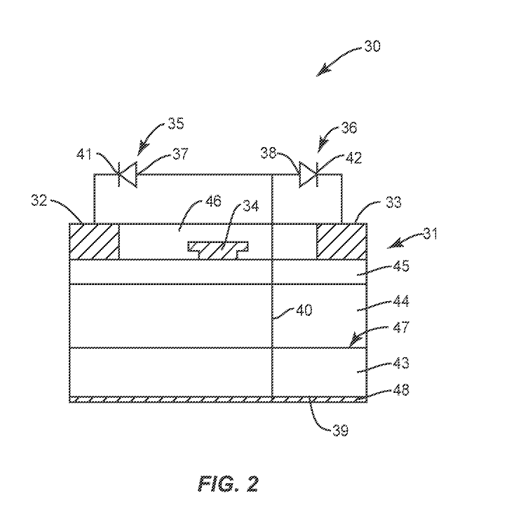

FIG. 2 illustrates a schematic cross-sectional view of a semiconductor device 30 including a Group III nitride-based High Electron Mobility Transistor (HEMT) 31 configured as a bidirectional switch. The Group III nitride-based HEMI 31 includes a first input/output contact pad 32, a second input/output contact pad 33 and a single gate 34 arranged between the first input/output contact pad 32 and the second input/output contact pad 33. A first diode 35 and a second diode 36 are coupled anti-serially between the first input/output contact pad 32 and the second input/output contact pad 33. An anode 37 of the first diode 35 and an anode 38 of the second diode 36 are coupled to a backside 39 of the HEMT 31 as is schematically in indicated in FIG. 2 by line 40. A cathode 41 of the first diode 35 is electrically coupled to the first input/output contact pad 32 and a cathode 42 of the second diode 36 is coupled to the second input/output contact pad 33.

The first diode 35 and the second diode 36 are capable of withstanding the blocking voltage rating of the HEMT 31. Due to the anti-serial arrangement of the diodes 35, 36 between the first input/output contact pad 32 and the second input/output contact pad 33, the backside of the HEMT is coupled to a potential near to source potential in both directions, i.e. when the first input/output contact pad 32 acts as the source and the second input/output contact pad 33 acts as the drain and when first input/output contact pad 32 acts as the drain and the second input/output contact pad 33 acts as the source.

The Group III nitride-based HEMT 31 may include a substrate 43, a channel layer 44 including gallium nitride GaN arranged on the substrate 43 and a barrier layer 45 including aluminium gallium nitride (AlₓGa₁₋ₓN, wherein 0<x<1) arranged on the channel layer 44. A two dimensional electron gas (2DEG) is formed at the interface between the barrier layer 45 and the channel layer 44 by induced and spontaneous polarization.

The first input/output contact pad 32, the gate 34 and the second input/output contact pad 33 may be arranged on the barrier layer 45. A passivation layer 46 may be arranged on regions of the barrier layer 45 exposed from the first input/output contact pad 32, the gate 34 and the second input/output contact pad 33. The substrate may include silicon, silicon carbide or sapphire, for example. The substrate 43 may include one or more buffer or transition layers between the upper surface 47 of the substrate and the channel layer 44.

An electrically conductive contact pad 48 may be arranged on the rear surface of the substrate 43. The contact pad 48 may enable the rear side of the HEMT 31 to be mounted on, and electrically coupled to, a contact pad of the rewiring substrate or a portion of an electrically conductive leadframe, for example. The electrical connection, indicated with the reference number 40 in FIG. 2, from the cathodes 37, 38 of the first diode 35 and second diode 36, respectively, may be provided within the body of the HEMT 31 or externally such that the anode 36 and anode 38 are electrically coupled with the contact pad 48 on the rear surface of the substrate 43.

The gate 34 may be positioned so as to provide substantially the same blocking capability in both directions. In some embodiments, the gate 34 may be arranged symmetrically between the first input/output contact pad 32 and the second input/output contact pad 33 such that it is equidistant from the first input/output contact pad 32 and the second input/output contact pad 33. The gate 34 may have a T-shape. The gate 34 may further include a gate insulation layer arranged between the gate metal and the barrier layer. The gate 34 may be a Schottky gate.

In some embodiments, the gate 34 may be arranged asymmetrically between the first input/output contact pad 32 and the second input/output contact pad 33 to provide a different blocking capability in the two opposing directions.

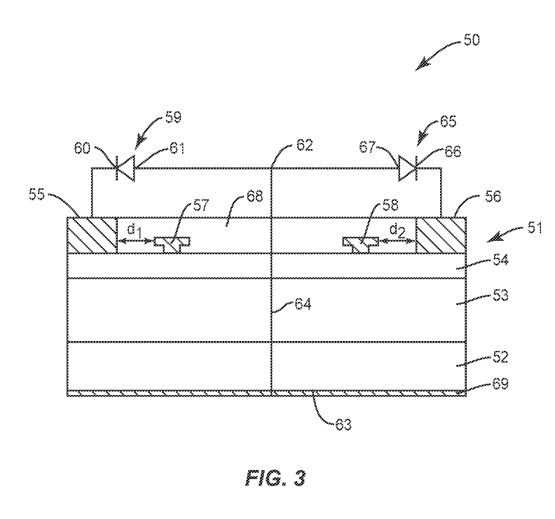

FIG. 3 illustrates a schematic cross-sectional view of a semiconductor device 50 including a gallium nitride-based High Electron Mobility Transistor (HEMT) 51 configured as a bidirectional switch. The semiconductor device 50 includes a substrate 52, a channel layer 53 including gallium nitride arranged on the substrate 52, and a barrier layer 54 including aluminium gallium nitride arranged on the channel layer 53. The HEMT 51 includes a first input/output contact pad 55 arranged on the barrier layer 54 and a second input/output contact pad 56 arranged on the barrier layer 54 spaced apart from the first input/output contact pad 55.

The HEMT 51 further includes two gates 57, 58 which are arranged on the barrier layer 54 spaced apart from one another. Each of the gates 57, 58 may include a T-shape. The first gate 57 is arranged at a distance d₁ from the first input/output contact pad 55. The second gate 58 is arranged at a distance d₂ from the second input/output contact pad 56. The distances d₁ and d₂ may be substantially the same. The distance between the two gates 57, 58 is larger than the distance between the gate 57, 58 and its respective input/output contact pad 55, 56.

The semiconductor device 50 further includes a first diode 59 with a cathode 60 and an anode 61. The first diode 59 is arranged such that its cathode 60 is electrically coupled to the first input/output contact pad 55 and its anode 61 is electrically coupled to a node 62. The node 62 is electrically coupled to the backside or rear surface 63 of the HEMT 51, as is indicated schematically by the line 64. The semiconductor device 50 further includes a second diode 65 including a cathode 66 which is electrically coupled to the second input/output contact pad 56 and an anode 67 which is electrically coupled to the node 62 and the backside 63 of the substrate 52. The first diode 59 and the second diode 65 are coupled anti-serially between the first input/output contact pad 55 and the second input/output contact pad 56.

The HEMT 51 may include a passivation layer 68 which is arranged on the barrier layer 54. The passivation layer 68 may cover the gates 57, 58 in the active region of the HEMT 51. A contact pad 69, which is electrically conductive, may be arranged on the rear surface 63 of the substrate 52.

A single transistor device, such as a Group III nitride-based HEMT, is configured as a bidirectional switch. In some embodiments, the diodes, which are coupled anti-serially between the first input/output contact pad and the second input/output contact pad of the transistor device, are provided by discrete components which may be electrically coupled to the first input/output contact pad and the second input/output contact pad by bond wires or other discrete electrical connectors such as contact clips. The discrete diodes may be electrically coupled to the rear surface of the transistor device by an electrically conductive via extending through the semiconductor body of the transistor device or by further discrete electrical connections between the electrically conductive substrate to which the rear surface of the transistor device is electrically coupled.

In some embodiments, the diodes are integrated into the transistor device providing the bidirectional switch. For example, one or more of the transistor cells may be configured as a diode and the one or more transistor cells electrically coupled to the remaining transistor cells of the transistor device such that the diode is coupled between one of the input/output contact pads and the rear surface of the substrate supporting the transistor device.

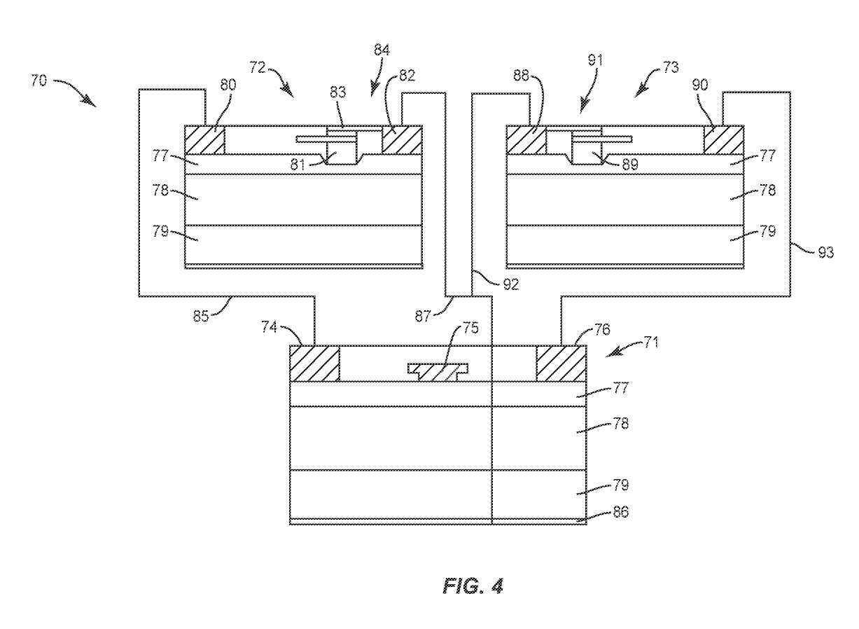

FIG. 4 illustrates a schematic view of a semiconductor device 70 including a transistor device 71 configured as a bidirectional switch, a first diode 72 and a second diode 73 which are integrated into the transistor device 71. In this embodiment., the transistor device 71 is a Group III nitride-based High Electron Mobility Transistor (HEMT) and the diodes 72, 73 are formed in the semiconductor body providing the HEMT.

The HEMT 71 includes a transistor structure configured as a bidirectional switch including a first input/output contact pad 74, a single gate 75 and a second input/output contact pad 76 arranged on a barrier layer 77 including aluminium gallium nitride AlₓGa₍₁₋ₓ₎N, where 0<x<1, which is arranged on a channel layer 78 including gallium nitride GaN which is in turn arranged on a substrate 79. The gate 75 is arranged between the first input/output contact pad 74 and the second input/output contact pad 76 such that it is substantially equidistant from the first input/output contact pad 74 and the second input/output contact pad 76.

The first diode 72 may be provided by one or more of the transistor cells of the HEMT 71. The first diode 72 includes a transistor structure including a first current electrode 80, a gate 81 and a second current electrode 82 which are arranged on the barrier layer 77. The second current electrode 82 is electrically coupled to the gate 81 by conductive structure 83 and forms the anode 84 of the diode 72. The first current electrode 80 forms the cathode of the diode 72 and is electrically coupled to the first input/output contact pad 74 of the transistor device 71 as is schematically illustrated in FIG. 4 by the line 85. The anode 84 is electrically coupled to the rear side 86 of the HEMT 71 as is schematically illustrated in FIG. 4 by the line 87.

The second diode 73 is also formed from one or more of the transistor cells and also has a transistor structure including a first current electrode 88, a gate 89 and second current electrode 90 arranged on the barrier layer 77. The first current electrode 88 is electrically coupled to the gate 89 and forms an anode 91 of the first diode 73. The anode 91 is electrically coupled to the anode 84 of the first diode 72 and to the rear surface 86 of the HEMT 71 as is schematically indicated by the line 92. The second current electrode 90 forms the cathode of the diode 73 and is electrically coupled to the second input/output contact pad 76 of the HEMT 71 as is schematically indicated by the line 93.

In this embodiment, the HEMT 71 is a depletion mode device, which is normally on. However, the transistor cells forming the diodes 72, 73 have an enhancement mode transistor structure. The enhancement mode transistor structure may be provided by providing a gate recess, i.e. by reducing the thickness of the barrier layer in the region under the gate, in the transistor cells forming the diodes 72, 73.

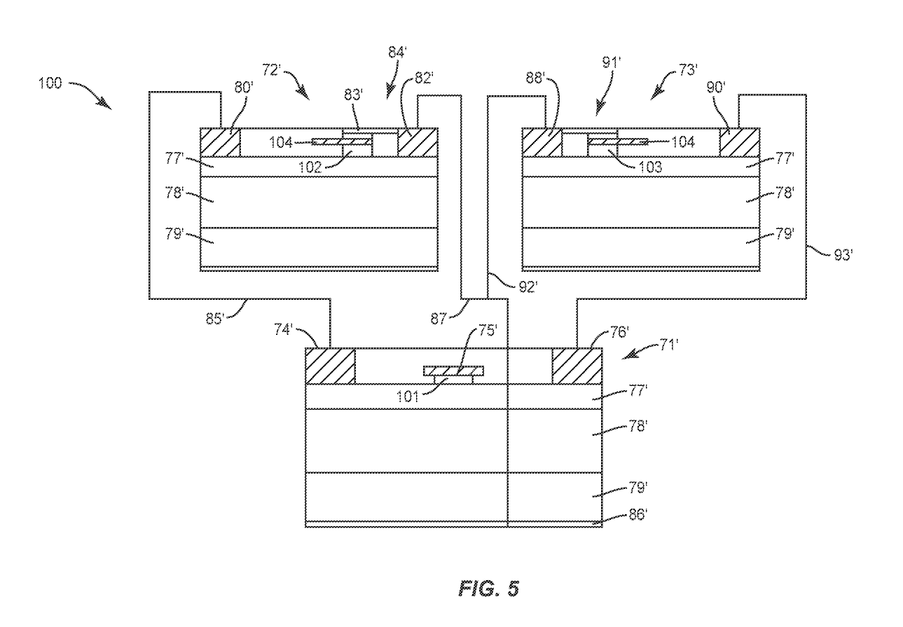

FIG. 5 illustrates a schematic view of a semiconductor device 100 including a Group III nitride-based HEMT 71′, a first diode 72′ and a second diode 73′ which each include a transistor structure and which are integrated into the HEMT 71′ as in the embodiment illustrated in FIG. 4. Like features are indicated like reference numbers denoted with a prime “′”.

The semiconductor device 100 differs from the semiconductor device 70 illustrated in FIG. 4 in that the HEMT 71′ is an enhancement mode device which is normally off. The arrangement of the HEMT 71 may be modified in various ways to transform the depletion mode device 71 into an enhancement mode device 71′. In the embodiment illustrated in FIG. 5, a p-doped GaN layer 101 is provided which is situated between the gate 75 and the barrier layer 77. In other embodiments, a recessed gate may be used to produce an enhancement mode device. The diodes 72′, 73′ also include a p-doped GaN region. 102, 103 between the barrier layer 77 and the gate metal 104 which forms part of the anode 84′ of the first diode 72′ and anode 91′ of the second diode 73′, respectively. The diodes 72′, 73′ are electrically coupled anti-serially between the first input/output contact pad 74° and the second input/output contact pad 76′ and such that the cathodes 84′, 91′ are electrically coupled to the rear 86′ of the HEMT 71′.

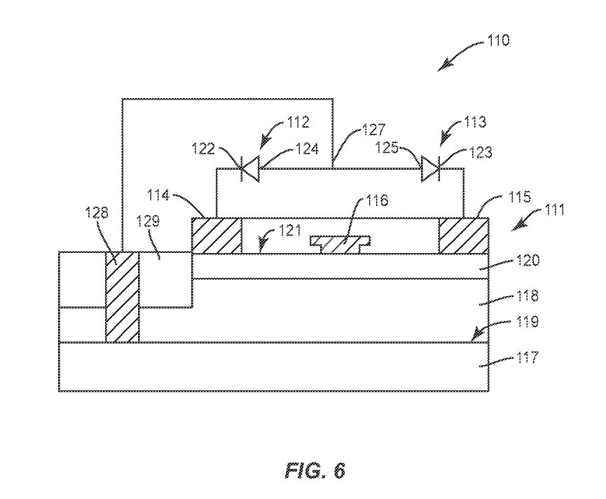

FIG. 6 illustrates a semiconductor device 110 including a Group III nitride-based High Electron Mobility Transistor 111 configured as a bidirectional switch, a first diode 112 and a second diode 113 which are coupled anti-serially between a first input/output contact pad 114 and a second input/output contact pad 115 of the HEMT 111, The HEMT 111 includes a single gate 116 arranged between the first input/output contact pad 114 and the second input/output contact pad 115. In other embodiments, two gates may be provided.

The semiconductor device 110 includes a substrate 117, a channel layer 118 including gallium nitride GaN arranged on the upper surface 119 of the substrate 117 and a barrier layer 120 arranged on the channel layer 118. The barrier layer 120 includes aluminium gallium nitride AlₓGa₍₁₋ₓ₎N, where 0<x<1 such that a two dimensional electron gas (2DEG) is formed at the interface between the barrier layer 120 and the channel layer 119 by induced and spontaneous polarization.

The first input/output contact pad 114, the second input/output contact pad 115 and the gate 116 may be arranged on the barrier layer 120. In some embodiments, the first input/output contact pad 114 and the second input/output contact pad 115 may extend through the barrier layer 120 and be in contact with the channel layer 118. The gate 116 may have a T-shape. The gate 116 may be arranged in a gate recess which protrudes into the upper surface 121 of the barrier layer 120, in which case, the thickness of the barrier layer 120 under the gate metal of the gate 116 is decreased.

The cathode 122 of the first diode 112 is coupled to the first input/output contact pad 114. The cathode 123 of the second diode 113 is electrically coupled to the second input/output contact pad 115. The anode 124 of the first diode 122 and the anode 125 of the second diode 113 are coupled to a node 127 which is in turn electrically coupled to the substrate 117 by way of a conductive via 128 which extends from the upper side surface of the barrier layer 120 through the channel layer 118 to the substrate 117. The conductive via 128 may be positioned adjacent the portion of the semiconductor substrate in which the HEMT 111 is positioned, for example, in an inactive region of the semiconductor device 110.

The region of the semiconductor device 110 surrounding the conductive via 128 may be insulated from the barrier layer 120 and 2 DEG formed at the interface between the barrier layer 120 and the channel layer 118 means of an electrically insulating layer 129. The insulation layer 129 may be arranged in a trench which extends through the barrier layer 120 and into the channel layer 118. In some embodiments, the side walls of the via in which the conductive via 128 is arranged may be lined with an electrically insulating layer. The conductive via 128 may also extend through the substrate 117 and be electrically coupled to a conductive pad arranged on the rear surface of the substrate 117. The cathodes 124, 125 of the anti-serially coupled diodes 112, 113 are electrically coupled to the rear surface of the HEMT 111 by means of the electrically conductive via 128.

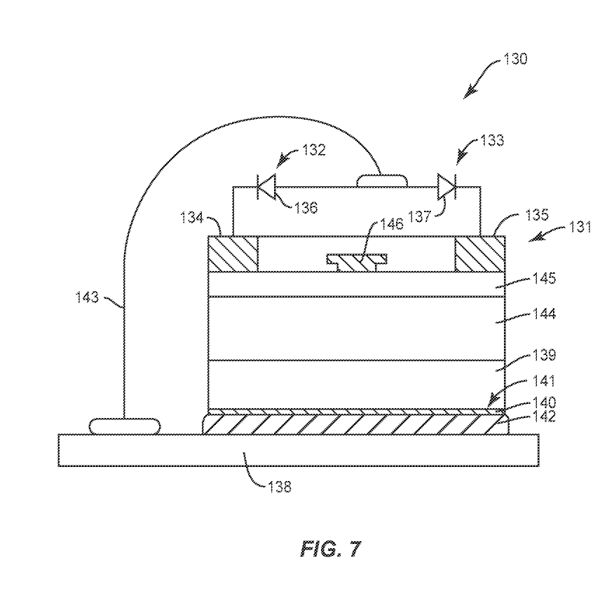

FIG. 7 illustrates a schematic view of a semiconductor device 130 including a HEMT 131 configured as a bidirectional switch and a pair of diodes 132, 133 coupled anti-serially between a first input/output contact pad 134 and a second input/output contact pad 135 of the HEMT 131. The cathodes 136, 137 of the diodes 132, 133 are electrically coupled to a support 138 on which the HEMT 131 is mounted. The HEMT 131 includes a substrate 139 including a contact area 140 on its rear surface 141 which is electrically coupled to the support 138 by, for example, a solder layer 142. The support 138 may be electrically conductive, for example portion of a leadframe, or may include an electrically conductive surface. The cathodes 136, 137 of the anti-serially coupled diodes 132, 133 may be electrically coupled to the support 138 by one or more bond wire connections 143 and to the rear surface 141 of the substrate 139 by way of the electrically conductive support 138 or a conductive trace extending between the end of the bond wire 143 attached to the support 138 and the rear surface 141 of the substrate 139 of the HEMT 131.

The HEMT 131 includes a gallium nitride channel layer 144, an aluminium gallium nitride barrier layer 145 arranged on the channel layer 144 and a gate 146 arranged on the barrier layer 145 such that it is positioned between the first input/output contact pad 134 and second input/output contact pad 135. The HEMT 131 may also include two gates which are independently operable.

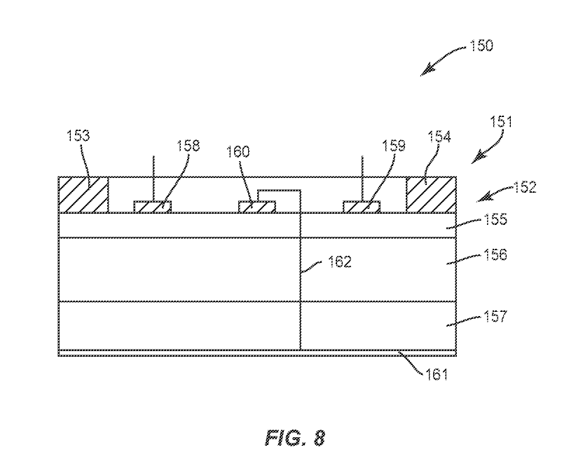

FIG. 8 illustrates a schematic view of a semiconductor device 150 including a bidirectional switch 151. The bidirectional switch 151 is formed by a Group III nitride-based HEMT 152 including a first input/output contact pad 153 spaced apart from a second input/output contact pad 154 arranged on an aluminium gallium nitride barrier layer 155 which is in turn arranged on a channel layer 156 including gallium nitride arranged on the substrate 157.

The bidirectional switch 151 includes two gates 158, 159 which are arranged spaced apart from one another and arranged between the first input/output contact pad 153 and the second input/output contact pad 154. The first gate 158 may be spaced from the first input/output contact pad 153 by a distance which is substantially the same as the distance between the second gate 159 and the second input/output contact pad 154. In the illustrated embodiment, the distance between the two gates 158, 159 is greater than the distance between the gate and its respective input/output contact pad. However, in other non-illustrated embodiments, the distance between the two gates 158, 159 is substantially the same as the distance between the gate and its respective input/output contact pad. The two gates 158, 159 are independently operable.

A further conductive contact 160 may be arranged substantially equidistant between the two gates 158, 159. The further conductive contact 160 may be a dedicated source or ground terminal. The further conductive contact 160 is electrically coupled to the rear surface 161 of the substrate 159, as is indicated schematically by line 162, and provides grounding for the rear side of the bidirectional switch 151.

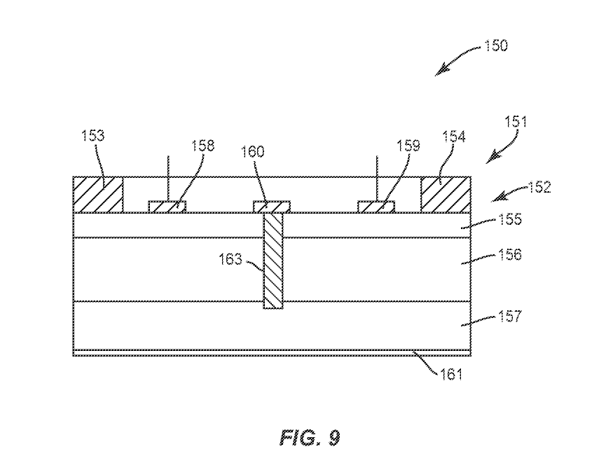

The conductive contact 160 may be coupled to the rear side 161 of the substrate 157 by any suitable means. In one embodiment, as illustrated in FIG. 9, the electrically conductive contact 160 is electrically coupled to the substrate 157 by at least one conductive via 163 which extends form the conductive contact 160 through the barrier layer 155 and the channel layer 156 such that it makes contact with the substrate 157. The conductive via 163 may extend to the rear surface 161 of the substrate 157. The via in the semiconductor material may be lined with an electrically insulated material to electrically insulate the electrically conductive via 163 from the semiconductor material of the barrier layer 155 and the channel layer 156.

The conductive contact 160 may also be coupled to the rear side 161 of the substrate 157 by one or more connections external to the semiconductor body of the semiconductor device 150. For example, the conductive contact 160 may be coupled to a conductive support on which the substrate 157 is arranged by one or more bond wires.

As discussed above, the Group III nitride-based High Electron Mobility Transistor which is configured as a bidirectional switch may include an enhancement mode device. The enhancement mode device may include a p-doped GaN layer or a p-doped aluminium gallium nitride layer arranged between the metal gate and the barrier layer.

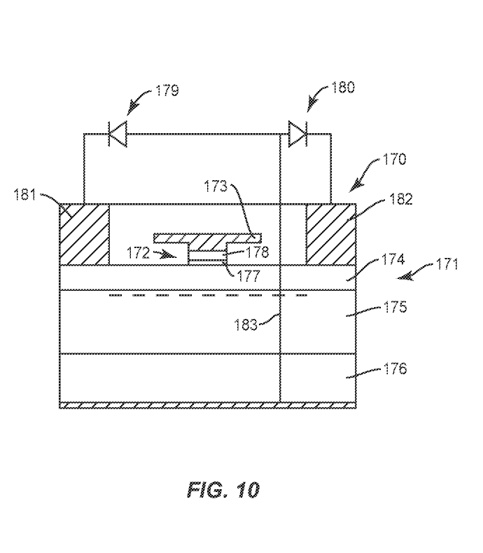

FIG. 10 illustrates a schematic view of an enhancement mode Group III nitride-based High Electron Mobility Transistor (HEMT) 170 configured as a bidirectional switch 171 which includes a p-doped Group III nitride-based layer 172 arranged between a T-shaped metal gate 173 and a barrier layer 174. The barrier layer 174 includes aluminium gallium nitride and is arranged on a channel layer 175 including gallium nitride which is in turn arranged on a substrate 176. The p-doped Group III nitride-based layer 172 includes two sub layers 177, 178. The first sublayer 177 is arranged on the barrier layer 174 and includes p-doped gallium aluminium gallium nitride. The second sublayer 179 is arranged on the first sublayer 178 and includes p-doped gallium nitride. The vertical portion of the T-shaped gate 173 is arranged on the p-doped gallium nitride layer 178. The lateral extent of both the sublayers 178, 179 may be substantially the same as the lateral extent of the base of the gate 173.

The HEMT 170 also includes two diodes 179, 180 coupled anti-serially between the first input/output electrode 171 and the second input/output electrode 172. The diodes 179, 180 are also coupled to the rear surface of the substrate 176 as is schematically indicated by line 183. The anodes of the diodes 179, 180 are coupled to the rear surface of the substrate 176. The cathodes of the diodes 179, 180 are electrically coupled to the first input/output electrode 171 and the second input/output electrode 172, respectively.

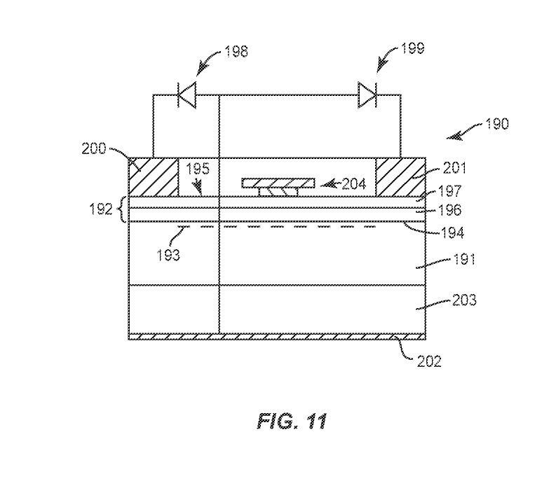

FIG. 11 illustrates a schematic view of a Group III nitride-based device 190 including a bidirectional switch. The Group III nitride-based HEMT 190 includes a channel layer 191 and a barrier layer 192 arranged on the channel layer 191. The channel layer 191 may include gallium nitride and the barrier layer 192 may include aluminium gallium nitride such that a two-dimensional electron gas (2DEG) 193 is formed at the interface between the aluminium gallium nitride layer and the gallium nitride layer. The composition of the barrier layer 192 may vary within the barrier layer 192.

The composition of the barrier layer 192 varies in directions substantially perpendicular to the two-dimensional electron gas 193. In particular, the aluminium content and, consequently, the gallium content may vary through the thickness of the barrier layer 192, for example, from the interface 194 between the barrier layer 192 and the channel layer 191 to the outermost surface 195 of the barrier layer 192. The composition may vary gradually providing a graded composition structure.

In some embodiments, the barrier layer 192 includes two or more sublayers 196, 197 of differing composition, in particular, aluminium gallium nitride of differing composition. The first sublayer 196 which is arranged on the channel layer 191 may include an aluminium content which is lower than the aluminium content of the second sublayer 197 which is arranged on the first sublayer 196. Two diodes 198, 199 are coupled anti-serially between a first input/output electrode 200 and a second input/output electrode 201 and the rear surface 202 of the substrate 203, thus coupling the rear surface 202 of the substrate 203 to near source potential.

A barrier layer including a spatially varying composition or two or more sublayers of differing composition is not limited to use in a Group III-nitride-based High Electron Mobility Transistor with the features illustrated in FIG. 11. For example, the barrier layer including a spatially varying composition or two or more sublayers of differing composition may be used in a Group III-nitride-based High Electron Mobility Transistor including a single gate or two independently operable gates and/or for a depletion mode or an enhancement mode Group III-nitride-based High Electron Mobility Transistor.

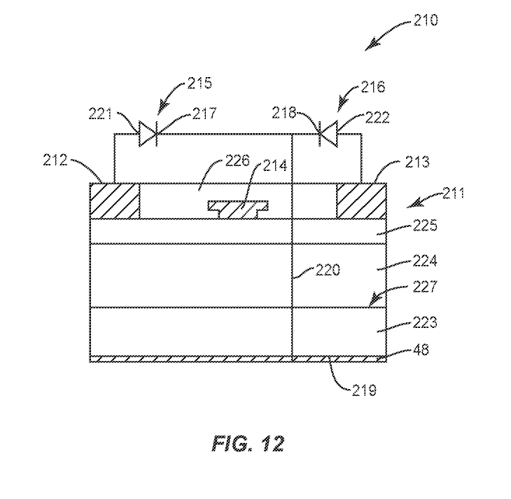

FIG. 12 illustrates a schematic cross-sectional view of a semiconductor device 210 including a Group III nitride-based High Electron Mobility Transistor (HEMT) 211 configured as a bidirectional switch in which the back side of the HEMT 211 is coupled to near drain potential. The Group III nitride-based HEMT 211 includes a first input/output contact pad 212, a second input/output contact pad 213 and a single gate 214 arranged between the first input/output contact pad 212 and the second input/output contact pad 213. A first diode 215 and a second diode 216 are coupled anti-serially between the first input/output contact pad 212 and the second input/output contact pad 213. A cathode 217 of the first diode 215 and a cathode 218 of the second diode 216 are coupled to the backside 219 of the HEMT 211 as is schematically indicated in FIG. 2 by line 220. An anode 221 of the first diode 215 is electrically coupled to the first input/output contact pad 212 and an anode 222 of the second diode 216 is coupled to the second input/output contact pad 213.

The electrical connection between the cathode 217 of the first diode 215, the cathode 218 of the second diode 216 and the backside 219 of the HEMT 211 may include one or more bond wires or one or more conductive vias, for example.

The first diode 215 and the second diode 216 are capable of withstanding the blocking voltage rating of the HEMT 211. Due to the anti-serial arrangement of the diodes 215, 216 between the first input/output contact pad 212 and the second input/output contact pad 213, the backside 219 of the HEMT 211 is coupled to a potential near to drain potential in both directions, i.e. when the first input/output contact pad 212 acts as the source and the second input/output contact pad 213 acts as the drain and when first input/output contact pad 212 acts as the drain and the second input/output contact pad 213 acts as the source.

The Group III nitride-based HEMT 211 may include a substrate 223, a channel layer 224 including gallium nitride GaN arranged on the substrate 223 and a barrier layer 225 including aluminium gallium nitride (AlₓGa₁₋ₓN, wherein 0<x<1) arranged on the channel layer 224. A two dimensional electron gas (2DEG) is formed at the interface between the barrier layer 225 and the channel layer 224 by induced and spontaneous polarization.

The gate 224 may be replaced by two independently operable gates. The diodes 215, 216 may be provided by discrete components or be integrated into the HEMT 211. The barrier layer may also include a spatially varying composition or two or more sublayers of differing composition.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures.

Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A switch circuit, comprising:
a bidirectional switch comprising a first input/output node, a second input/output node, a first diode and a second diode, wherein the first diode and the second diode are coupled anti-serially between the first input/output node and the second input/output node.

2. The switch circuit of claim 1, wherein the bidirectional switch comprises a Group III-nitride-based High Electron Mobility Transistor (HEMT).

3. The switch circuit claim 2, wherein an anode of the first diode and an anode of the second diode are coupled to a same node.

4. The switch circuit of claim 3, wherein the node is electrically coupled to the back side of the Group III-nitride-based HEMT.

5. The switch circuit of claim 2, wherein the Group III-nitride-based HEMT comprises a single gate or two independently operable gates.

6. The switch circuit of claim 1, wherein the first diode and the second diode comprise discrete components.

7. The switch circuit of claim 2, wherein the first diode and the second diode are integrated into the Group III-nitride-based HEMT.

8. A semiconductor device, comprising:
a Group III-nitride-based High Electron Mobility Transistor (HEMT) configured as a bidirectional switch and comprising a first input/output contact pad, a second input/output contact pad, one or more gates arranged between the first input/output contact pad and the second input/output contact pad, a first diode and a second diode, wherein the first diode and the second diode are coupled anti-serially between the first input/output contact pad and the second input/output contact pad.

9. The semiconductor device of claim 8, wherein an anode of the first diode and an anode of the second diode are coupled to a back side of the Group III-nitride-based HEMT.

10. The semiconductor device of claim 8, wherein a cathode of the first diode and a cathode of the second diode are coupled to a back side of the Group III-nitride-based HEMT.

11. The semiconductor device of claim 8, wherein the first diode and the second diode each comprise a transistor structure comprising a first current electrode, a gate and a second current electrode, wherein the gate is electrically coupled to the first current electrode.

12. The semiconductor device of claim 11, wherein the transistor structure comprises an enhancement mode transistor structure.

13. The semiconductor device of claim 8, wherein the Group III-nitride-based HEMT comprises an enhancement mode device or a depletion mode device.

14. The semiconductor device of claim 8, wherein the Group III-nitride-based HEMT comprises a channel layer and a barrier layer arranged on the channel layer.

15. The semiconductor device of claim 14, wherein the channel layer comprises GaN and the barrier layer comprises AlₓGa₍₁₋ₓ₎N, wherein 0<x<1.

16. The semiconductor device of claim 8, wherein the one or more gates comprise at least one p-doped Group III nitride.

17. The semiconductor device of claim 16, wherein the p-doped Group III nitride comprises at least one of a p-doped GaN layer and a p-doped Al_{z}Ga_{(1-z)}N layer, wherein 0<z<1.

18. A method, comprising:
coupling a back side of a High Electron Mobility Transistor (HEMT) configured as a bidirectional switch to a near source potential by coupling a first diode and a second diode anti-serially between a first input/output contact pad and a second input/output contact pad of the HEMT.

19. The method of claim 18, wherein an anode of the first diode and an anode of the second diode are coupled to the back side of the HEMT, wherein a cathode of the first diode is coupled to the first input/output contact pad, and wherein a cathode of the second diode is coupled to the second input/output contact pad.

20. A method, comprising:
coupling a back side of a High Electron Mobility Transistor (HEMT) configured as a bidirectional switch to a near drain potential by coupling a first diode and a second diode anti-serially between a first input/output contact pad and a second input/output contact pad of the HEMT.

21. The method of claim 20, wherein a cathode of the first diode and a cathode of the second diode are coupled to the back side of the HEMT, wherein an anode of the first diode is coupled to the first input/output contact pad, and wherein an anode of the second diode is coupled to the second input/output contact pad.

22. A semiconductor device, comprising:
a Group III-nitride-based. High Electron Mobility Transistor (HEMT) configured as a bidirectional switch and comprising a first input/output contact pad, a second input/output contact pad, two independently operable gates arranged between the first input/output contact pad and the second input/output contact pad, and a further pad, wherein the further pad is coupled to a rear side of the Group III-nitride-based HEMT.

23. The semiconductor device of claim 22, wherein the further pad is arranged between the two independently operable gates.

24. The semiconductor device of claim 22, wherein the further pad is arranged on a barrier layer of the Group III-nitride-based HEMT and is electrically coupled to the rear side of the Group III-nitride-based HEMT by a conductive via, or an electrical connection external to the Group III-nitride-based HEMT.
